(19) United States
(12) Patent Application Publication
(10) Pub. No.: US 2025/0230535 A1
(43) Pub. Date: Jul. 17, 2025

(54) METHOD AND DEVICE FOR FORMING A FLUORIDE OR OXYLFLUORIDE LAYER FOR AN OPTICAL ELEMENT FOR THE VUV WAVELENGTH RANGE, AND OPTICAL ELEMENT COMPRISING SAID FLUORIDE OR OXYLFLUORIDE LAYER

(71) Applicant: Carl Zeiss SMT GmbH, Oberkochen (DE)

(72) Inventors: Felix Lange, Nattheim (DE); Alexander Wiegand, Aalen (DE); Marcel Haerting, Aalen (DE); Katja Schick, aalen (DE); Christian Sack, Schorndorf (DE)

(21) Appl. No.: 19/097,344

(22) Filed: Apr. 1, 2025

Related U.S. Application Data
(63) Continuation of application No. PCT/EP2023/077210, filed on Oct. 2, 2023.

(30) Foreign Application Priority Data
Oct. 5, 2022 (DE) 102022210513.3

(51) Int. Cl. C23C 8/36; G02B 1/14

(52) U.S. Cl. CPC C23C 8/36; G02B 1/14

(57) ABSTRACT

Methods of forming a fluoride or oxyfluoride layer for an optical element for use in the VUV wavelength range, which methods comprise: depositing an oxide layer; and converting the oxide layer into the fluoride or oxyfluoride layer by irradiating the oxide layer with UV/VUV radiation in the presence of an active fluorination agent. An optical arrangement has at least one such optical element. An associated device for forming a fluoride or oxyfluoride layer for an optical element is designed for use in the VUV wavelength range.

### CROSS-REFERENCE TO RELATED APPLICATIONS

The present application is a continuation of, and claims benefit under 35 USC 120 to, international application No. PCT/EP2023/077210, filed Oct. 2, 2023, which claims benefit under 35 USC 119 of German Application No. 10 2022 210 513.3, filed Oct. 5, 2022. The entire disclosure of each of these applications is incorporated by reference herein.

### FIELD

The disclosure relates to a method for forming a fluoride or oxyfluoride layer for an optical clement for use in the VUV wavelength range. The disclosure also relates to an optical element for use in the VUV wavelength range comprising (at least) one fluoride or oxyfluoride layer that is formed by the method and to an optical arrangement for the VUV wavelength range having at least one such optical element. The disclosure also relates to a device for forming a fluoride or oxyfluoride layer for an optical element, which is designed for use in the VUV wavelength range.

In this application, the VUV wavelength range is understood to mean the wavelength range of electromagnetic radiation between 115 nanometers (nm) and 190 nm. The VUV wavelength range is of importance for microlithography for example. For instance, radiation in the VUV wavelength range is used in projection exposure apparatuses and wafer or mask inspection apparatuses, for example.

### BACKGROUND

Optical elements having at least one fluoride layer are frequently used in such apparatuses. Highly reflective optical elements for the VUV wavelength range typically have a fluoride layer, for example, in order to protect an underlying metallic reflection layer, off which the radiation is reflected, against oxidation. For instance, DE 10 2018 211 499 A1 discloses a reflective optical clement having a substrate, a metal layer, a metal fluoride layer applied to the metal layer and an oxide layer applied to the metal fluoride layer, and also a method for the production thereof. In this case, the oxide layer reduces the degradation at the high radiation intensities used in lithography and hence extends the service life of the optical element. Layer stacks composed of different fluorides or fluorides and oxides may additionally also be used for the reflective coating or antireflective coating of optical elements.

However, the small band gap of most oxides can lead to a high absorption in the VUV wavelength range. As a consequence, fluorides can be used as layer materials.

However, high radiation intensities as used in optical arrangements in the form of wafer or mask inspection apparatuses and projection exposure apparatuses can lead to degradation of the fluorides and of the optical elements in general, which can shorten the service life thereof. This degradation can be counteracted by way of the deposition of high-density fluoride layers.

In general, high-density solids, for example high-density fluoride layers, can be produced by way of plasma-assisted deposition methods, e.g. by sputter deposition, for example by ion beam sputtering (IBS), or by plasma ion-assisted deposition (PIAD). A reactive gas is generally offered during such deposition processes in order to compensate for the preferential sputtering of lighter elements (in this case: O, F) and hence preserve the stoichiometry of the deposited layers. In the context of oxide layer deposition, such a reactive gas can be, e.g., O₂. For fluoride deposition, F₂ may be offered accordingly, for example as described in the article “Plasma-assisted deposition of metal fluoride coatings and modeling the extinction coefficient of as-deposited single layers”, M. Bischoff et al., Appl. Opt. 50, 232-238 (2010), in which metal fluoride layers are deposited via plasma-assisted electron beam deposition. Even though F₂ is an attractive active fluorination agent from a scientific point of view, gaseous fluorine can be accompanied by significant challenges in practical use, making the use of F₂ as a process gas potentially more difficult. For example, comprehensive safety infrastructure is typically used on account of the corrosivity and toxicity of F₂—in contrast to O₂.

Other gaseous active fluorination agents, e.g., SF₆, CF₄ or NF₃, are potentially undesirable in that sulfur, carbon or nitrogen is introduced into the deposited layer by way of the momentum transfer in a plasma-assisted and/or ion-assisted process. The optical performance—especially in the VUV wavelength range—can suffer due to the introduction of these foreign atoms into the deposited layers. For example, this can lead to increased absorption or extinction of the layers.

To reduce the absorption of the fluoride layers and the degradation thereof, it is known to propose an aftertreatment of the fluoride layers. Aftertreatment means that the treatment is implemented after the deposition of the fluoride layers has been completed. However, many of the known aftertreatment methods can be undesirable in that they are performed at elevated temperature or in that effective aftertreatment involves an elevated temperature.

For example, US 2004/0006249 A1 describes a method for postfluorination of fluoride layers. Postfluorination can occur in the temperature range between 10° C. and 150° C. and at a fluorine concentration of between 1000 ppm and 100%.

Further, the literature describes that an aftertreatment in the form of subsequent irradiation with UV light may improve the optical performance of plasma-(ion-) assisted deposition fluorides deposited in the DUV wavelength range. For example, the article by M. Bischoff et al., cited above, also describes the aftertreatment of metal fluoride layers with UV radiation. The article showed that the initially poor transmission of LaF₃, MgF₂ and AlF₃ layers in the DUV wavelength range can be significantly increased by this aftertreatment. During this subsequent irradiation, color centers are bleached, and presumably unsaturated bonds are (superficially) post-oxidized.

While this procedure is practicable for oxides in general and for fluorides for use in the DUV wavelength range (i.e. at wavelengths greater than 190 nm), it is generally eliminated for fluorides in the VUV wavelength range. In the latter case, oxidation leads to the loss of optical performance.

DE 10 2021 200 490 A1 also describes an aftertreatment of a metal fluoride layer by irradiation, wherein electromagnetic radiation having at least one wavelength below 300 nm is used. The metal fluoride layer is applied on a metal layer of a reflective optical element for use in the UV wavelength range. The irradiation results in a passivation of the metal fluoride layer which counteracts degradation of the metal layer. However, the passivating protective layer is typically an oxide layer, which can lead to disadvantages described above.

Irradiation with UV light may also be implemented supportingly with the deposition of layers, for nanostructuring or during the operation of a microlithography apparatus.

DE 10 2018 221 190 A1 discloses the nanostructuring of a substrate for transmission of radiation in the FUV/VUV wavelength range by introducing an energy input, e.g. by irradiation with UV/VUV radiation. In that case, the substrate is crystalline; for example the substrate is an MgF₂ single crystal. The irradiation enables the surface of the MgF2 single crystal to be reorganized in such a way that an antireflective effect occurs.

DE 10 2021 201 477 A1 also discloses a method for operating a microlithographic optical arrangement which has an optical element having a fluoride coating or composed of a fluoride substrate. In that case, for annealing defects of the fluoride, during operation, the optical element is irradiated with UV light with wavelengths which are greater than the wavelength of operating light of the optical arrangement, which is less than or equal to 300 nm.

Finally, further methods for producing fluoride layers or optical elements with fluoride layers are known, in which other strategies are used to reduce the absorption and/or the degradation.

For example, DE 10 2005 017 742 A1 discloses a method for coating a substrate by plasma-assisted deposition of a coating material, for example a fluoride material. The plasma contains ions having a relatively low effective ion energy, while the effective energy per molecule is relatively high, which is intended to lead to low absorption and contamination of a deposited layer with at the same time a high packing density.

DE 10 2020 208 044 A1 discloses a method for producing an optical element, for example a mirror, window or beam splitter, for the VUV wavelength range having a coating with a fluorine scavenger layer, which can be applied to a fluoride layer. The purpose of the fluorine scavenger layer is to prevent the degradation of the fluoride layer, with an attendant longer lifetime of the optical element. The underlying mechanism is a significant reduction of the mobility of interstitial fluorine atoms by so-called fluorine scavengers in the fluorine scavenger layer.

Further variants of physical vapor deposition for fluoride layers are also described in US 2013/0122252 A1, JP 11172421A and JP 2003193231A2.

### SUMMARY

The disclosure seeks to provide a method and a device for forming a fluoride or oxyfluoride layer and also an optical element and an optical arrangement having such an optical element, which allow high optical performance or have high optical performance.

According to a first aspect, the disclosure provides a method, comprising: depositing an oxide layer; and converting the oxide layer into the fluoride or oxyfluoride layer by irradiating the oxide layer with UV/VUV radiation in the presence of an active fluorination agent. The oxide layer may be deposited directly on a substrate. However, it is also possible that the oxide layer is deposited on a further layer which was applied to a substrate in advance (see below).

In the context of this application, UV/VUV radiation denotes electromagnetic radiation in the wavelength range between 115 nm and 350 nm. The fluoride layer can be irradiated with VUV radiation in the wavelength range between 115 nm and 190 nm in the presence of the active fluorination agent (see above).

In a method according to the disclosure, a (typically dense) oxide layer is initially deposited in a coating process. Subsequently, the offer of a suitable active fluorination agent leads to the oxide layer being converted into a fluoride layer or into an oxyfluoride layer with the aid of UV/VUV radiation. The active fluorination agent can be a gaseous substance which photodissociates as a consequence of irradiation by UV/VUV radiation and in the process forms molecular and/or atomic, especially also ionized and/or excited, fluorine (referred to as fluorine species in encompassing fashion below). The reactive fluorine species can lead to a chemical conversion of the oxide into a fluoride, at least in the region of the surface of the oxide layer. The entire oxide layer may be converted into a fluoride layer. However, it is also possible that the oxide layer is converted into a fluoride only in the vicinity of the surface, and an oxyfluoride layer is formed in the residual volume. In the latter case, the layer is referred to as oxyfluoride layer within the present application. Complete conversion of the oxide layer into a fluoride layer could be demonstrated experimentally for an oxide-layer layer thickness of less than approximately 10 nm. However, complete conversion may also occur for greater layer thicknesses since the (stoichiometric) fluorination front can be pushed deeper as the duration of irradiation increases.

Since the conversion of the oxide into the fluoride is driven chemically, it is generally possible in comparison with a coating process to manage with less critical active fluorination agents, e.g., NF₃, during the aftertreatment or conversion process. Moreover, the amount of active fluorination agent used can be reduced in comparison with a coating process. The reduction in active fluorination agent amount may be compensated for by a lengthening of the time of the fluorination process. Both measures (the use of less critical active fluorination agents and the reduction in the active fluorination agent amount) can help ensure that the desired safety infrastructure may be relaxed in comparison with a fluorine-assisted coating process using F₂.

In a variant, the oxide layer is deposited by way of a PVD (“physical vapor deposition”) deposition process, optioneally selected from the group comprising: sputter deposition, for example magnetron sputtering, ion beam sputtering (IBS), ion beam-assisted sputtering (IBAS) and plasma ion-assisted deposition (PIAD). The oxide layer is typically deposited by a coating method that allows the deposition of dense layers; plasma-assisted or ion-assisted processes are desirable to this end. As described further above, the oxide layer may be deposited in the presence of a gaseous oxidation material in order to preserve the stoichiometry of the deposited oxide layer. For example, a reactive gas in the form of O₂, H₂O, H₂O₂, . . . may be used as oxidation material.

In a further variant, the oxide layer is deposited using a CVD (“chemical vapor deposition”) deposition process, for example comprising an atomic layer deposition process (ALD) or a plasma-enhanced atomic layer deposition process (PEALD). Atomic layer deposition allows the deposition of extremely thin layers, down to atomic monolayers.

In a further variant, the oxide layer is deposited in a coating chamber, and the oxide layer is converted into the fluoride or oxyfluoride layer in a fluorination chamber that is spatially separate from the coating chamber. For fluorination or conversion of the oxide layer, the substrate with the deposited oxide layer is transferred from the coating chamber to the fluorination chamber. The transfer may be performed manually or in automated fashion.

The assisted deposition of a fluoride layer in a coating chamber, within the scope of which an active fluorination agent is offered, can have an issue that the fluorine gas of the active fluorination agent reacts strongly with hot components in the coating chamber (e.g., with the electrode of the plasma source or with an evaporator boat used during evaporation) and generally has significant contamination in the deposited layer as a consequence. This can be avoided by the fluorination process described here, which follows the coating and generally manages without elevated temperatures. The present variant for performing the aftertreatment or fluorination can make use of a dedicated, fluorine-resistant fluorination chamber, the interior of which has a protective gas atmosphere and which is resistant to reactive fluorine species (see below).

In a further variant, the UV/VUV radiation has a first spectral range serving for photodissociation of the active fluorination agent and comprising at least one wavelength whose energy Eₚₕ is at least equal to the dissociation energy E_{diss} of the active fluorination agent. The dissociation energy, E_{diss}, in this case denotes the energy to split the chemical bond of the active fluorination agent via electromagnetic radiation (light).

The first spectral range can mainly comprise, optionally exclusively comprise, wavelengths whose energy, Eₚₕ, is at least equal to the dissociation energy, E_{diss}, of the active fluorination agent. In this case, the following relation applies to all photons of the first spectral range:

E_{diss}≤Eₚₕ.

It may further be desirable to limit the first spectral range toward higher energies, in such a way that potentially negative and/or competing effects are suppressed or reduced in terms of their rate. Thus, E_{UP} can be chosen to be less than a threshold energy, above which negative and/or competing effects are amplified or only occur in the first place, where E_{UP} is the highest energy of the first spectral range, i.e. Eₚₕ≤E_{UP} applies. Examples of such negative and/or competing effects include the absorption of light in the solid body and the photodissociation of potentially oxidizing species (e.g. O₂ and H₂O) in the gaseous phase.

In a development, the highest energy, E_{UP}, of the first spectral range is no more than 100%, such as no more than 50%, greater than the dissociation energy of the active fluorination agent.

In a further variant of the method, the highest energy of the first spectral range is no more than the band gap energy, E_{G}, of the fluoride or oxyfluoride layer to be formed, such as no more than 75% of the band gap energy of the fluoride or oxyfluoride layer. This reduces the photoabsorption in the fluoride or oxyfluoride layer, and hence potentially reduces the formation of point defects (e.g. F centers).

To reduce the photodissociation of potentially oxidizing species (e.g. O₂ and H₂O) in the gaseous phase, it is further desirable to limit the first spectral range to lower and higher energies, in such a way that the effective rate of formation of potentially fluorinating species r_{fluorinating}, such as e.g. F, F₂, F⁻, F* or HF, is greater than the rate of potentially oxidizing species r_{oxidizing}, such as e.g. O, O₂, O*, O⁻, OH* and OH⁻:

r_{fluorinating}>r_{oxidizing}.

In a further variant of this method, the UV/VUV radiation includes a second spectral range for mobilizing atoms at the surface, at the grain boundaries and/or in the grain volume of the oxide layer, the second spectral range lying in an energy range of between 75% and 100%, such as between 80% and 95%, of a band gap energy of the fluoride or oxyfluoride layer. For example, the energy of the light in the second spectral range is higher than the binding energy of the corresponding atoms in the solid.

High-energy electromagnetic radiation near the band edge of the oxide can make it possible for surface atoms or atoms to be mobilized, without these atoms being desorbed, as described for example in DE 10 2018 221 190 A1, cited in the introduction. This increased mobility may contribute to transporting the active fluorination agent offered superficially or the fluorine species into the volume of the oxide layer as well, presumably predominantly via grain boundaries. Hence, depth fluorination may be assisted in this way, whereby the optical performance is improved. Moreover, it is possible that intrinsic point defects in the grain volume may be addressed by way of this increased diffusion.

In a further variant, the UV/VUV radiation or further electromagnetic radiation additionally used to irradiate the fluoride or oxyfluoride layer formed during the conversion includes a spectral range that serves to anneal at least one crystal defect of the fluoride or oxyfluoride layer and at least partly overlaps with an absorption range of the at least one crystal defect, the spectral range can comprise an absorption energy of the crystal defect, a mean energy of the spectral range more optionally deviating from the absorption energy of the crystal defect by no more than 0.5 electron-Volts (eV), such as by no more than 0.25 eV. Irradiation for annealing the at least one crystal defect may be implemented during the conversion of the oxide layer into the fluoride or oxyfluoride layer or following the conversion.

A potential problem with the irradiation by VUV radiation lies in the fact that the latter may cause crystal defects, for example F/H center defect pairs, in the fluoride or in the oxyfluoride by way of single-photon processes. These crystal defects can be annealed using the irradiation in a spectral range that at least partly overlaps with the absorption range.

The absorption energy of the crystal defect is understood to mean that energy or wavelength at which the absorption coefficient of the crystal defect has a maximum. The absorption range of the crystal defect is understood to mean a range in which the absorption coefficient is greater than one hundredth of the value at the maximum of the absorption coefficient. The absorption energies of crystal defects of a plurality of fluorides that are relevant to the present applications are indicated below by way of example: MgF₂: 260 nm (4.77 eV), AlF₃: 190 nm (6.53 eV), 170 nm (7.29 eV), LaF₃: 459 nm (2.7 eV), 564 nm (2.2 eV), 729 nm (1.7 eV).

In a further variant of this method, the oxide layer is irradiated in a protective gas atmosphere. The protective gas can be transparent to electromagnetic radiation in the UV/VUV wavelength range. Further, protective gases that are comparatively unreactive vis-à-vis optically relevant oxides and fluorides can be desirable. Inert gases in the form of the light noble gases—helium, neon and argon—are particularly suitable as protective gas, with argon being particularly well suited. Mixtures of noble gases, for example of the noble gases mentioned, can also be used as protective gas. As described further above, the oxide layer is typically irradiated in a fluorination chamber with that protective gas atmosphere in its interior.

In a further variant of this method, the active fluorination agent comprises at least one substance selected from the group of: F₂, HF, XeF₂, NF₃, CF₄, SF₆. As described further above, an active fluorination agent that is less critical than F₂, for example NF₃, may be chosen for the conversion or fluorination.

In a further variant of this method, the partial pressure of the active fluorination agent lies between 0.05 and 10⁶ parts per million by volume (ppmV), such as between 0.075 ppmV and 50 ppmV, for example between 0.1 ppmV and 10 ppmV, during the irradiation of the oxide layer. The partial pressure of the active fluorination agent may be set or specified during the irradiation. It is also possible that the partial pressure of the active fluorination agent is controlled to a target value while the oxide layer is irradiated.

In a further variant, the oxide layer is deposited in the form of an MgO layer, an Al₂O₃ layer, an La₂O₃ layer, a Gd₂O₃ layer, a CaO layer, an SrO layer or a BaO layer. The first three oxides specified here and their corresponding fluorides—MgF₂, AlF₃ and LaF₃—have great relevance in the optical industry. The further specified oxides and their corresponding fluorides—GdF₃, CaF₂, SrF₂ and BaF₂—are also used in the optical industry. The chemically driven conversion of the oxide layer into the fluoride or oxyfluoride layer can work particularly well whenever the corresponding fluoride MₓF_{Y} (M=metal, F=fluorine) is more stable than the oxide MₐO_{b}. This can hold particularly true for MgO, which has a pronounced energetic driving force for converting the oxide (MgO) into the corresponding fluoride (MgF₂). In the case of Al₂O₃/AlF₃, the formation enthalpies of the oxide and the fluoride are approximately the same, which is why the conversion works slightly less well than in the MgO/MgF₂ conversion.

In a further variant, the oxide layer is converted into a fluoride or oxyfluoride layer in the form of an MgF₂ layer, an MgₓO_{y}F_{z} layer, an AlF₃ layer, an AlₓO_{y}F_{z} layer, an LaF₃ layer, an LaₓO_{y}F_{z} layer, a GdF₃ layer, a GdₓO_{y}F_{z} layer, a CaF₂ layer, a CaₓO_{y}F_{z} layer, an SrF₂ layer, an SrₓO_{y}F_{z} layer, a BaF₂ layer or a BaₓO_{y}F_{z} layer. As described further above, the oxide is typically converted substantially completely into a fluoride at the surface or at a small distance from the surface of the oxide layer. The oxide layer is typically fully converted into a fluoride layer should the oxide layer have a small thickness, typically in the order of 5 nm-10 nm for example. Should the oxide layer be thicker, it is possibly only a volume region of the oxide layer adjacent to the surface of the oxide layer irradiated by VUV radiation that is converted into a fluoride, while an oxyfluoride forms at a greater distance from the surface. In this case, the conversion gives rise to an oxyfluoride layer MₓO_{y}F_{z} (M=metal) with a varying stoichiometry, i.e. the proportions x, y, z generally vary depending on distance from the surface of the oxyfluoride layer. Increasing the duration of irradiation allows the (stoichiometric) fluorination front to be pushed deeper. Fluoride layers with a thickness even greater than 10 nm may be created in this way.

In a further variant, a metallic reflection layer, for example an aluminum layer, is deposited on the substrate before the oxide layer is deposited. As described above, the number of materials that can be used to reflect VUV radiation is limited. Typically, an aluminum layer that can be protected against ambient influences by a dense layer is used as metallic reflection layer, for example as is described in DE 10 2018 211 499 A1 cited at the outset. In the example described here, the metallic reflection layer, typically in the form of an aluminum layer, is initially applied to a substrate. Subsequently, the oxide layer (e.g. MgO) that is as dense as possible is deposited on the metallic reflection layer with plasma or ion assistance. The metallic reflection layer and the oxide layer are typically deposited in one and the same coating chamber. This oxide layer is subsequently converted into a fluoride or oxyfluoride layer by the above-described fluorination process, for the purpose of which the coated substrate is typically transferred from the coating chamber to a fluorination chamber. As described further above, the optical performance of the reflective optical element produced by the method can be significantly increased for the VUV wavelength range by the conversion of the oxide into an (oxy)fluoride.

In a development of this variant, a further fluoride layer is deposited on the substrate before the oxide layer is deposited. In this case-unlike what was described above-the oxide layer is not deposited directly on the metallic reflection layer; instead, a fluoride layer (e.g. MgF₂, AlF₃, . . . ) is initially deposited on the metallic reflection layer. The thin, ion-assisted or plasma-assisted deposition oxide layer is applied to this layer stack and is converted into a fluoride or oxyfluoride layer in the manner described further above.

In both of the above-described cases, the method can be used to realize an optical element in the form of a broadband reflective mirror which firstly is well-protected against ambient influences and secondly has a high optical performance.

A further aspect of the disclosure relates to an optical element for use in the VUV wavelength range, comprising a fluoride or oxyfluoride layer that is formed by the above-described method. The optical element may be a reflective optical element in the form of a fluoridically protected or passivated metal mirror for example, as described above. However, the optical element may also be a purely fluoridic system that does not contain any metallic reflection layer; for example, it may be a transmissive optical element applied to which is an antireflective or highly reflective coating for the VUV wavelength range or a partly transmissive optical element, e.g., in the form of a beam splitter. The antireflective or highly reflective coating is typically a dielectric multilayer coating comprising one or more fluoride layers.

A further aspect of the disclosure relates to an optical arrangement for the VUV wavelength range, for example a VUV lithography apparatus or a wafer inspection system, comprising at least one optical element as described above. The optical arrangement may, for example, be a (VUV) lithography system, a wafer or mask inspection system, a laser system, etc.

Finally, a further aspect of the disclosure relates to a device for forming a fluoride or oxyfluoride layer for an optical element, which is designed for use in the VUV wavelength range, by converting an oxide layer into the fluoride or oxyfluoride layer, comprising: a fluorination chamber; a supply unit for supplying inert gas and an active fluorination agent into the fluorination chamber, the inner side of the fluorination chamber being resistant to the active fluorination agent and its conversion products; and at least one UV/VUV radiation source for irradiating the oxide layer with UV/VUV radiation in the presence of the active fluorination agent in the fluorination chamber in order to convert the oxide layer into the fluoride or oxyfluoride layer. The fluorination chamber typically comprises a substrate holder used to hold a substrate which was introduced into the fluorination chamber and on which the oxide layer is applied (optionally on a further, underlying layer).

With regard to the features achieved with the device, reference should be made to the above explanations regarding the method according to the disclosure and its variants.

The UV/VUV radiation emitted by the UV/VUV radiation source is partly absorbed by the active fluorination agent. The fluorine species formed as a consequence by photodissociation of the active fluorination agent bring about a conversion of the oxide layer into a fluoride or oxyfluoride layer.

The UV/VUV radiation source is designed for photodissociation of the active fluorination agent and typically emits radiation in a wavelength range optionally lying between 115 nm and 1000 nm, such as between 120 nm and 170 nm, for example between 140 nm and 170 nm. For example, the UV/VUV radiation source may be a D₂ lamp (deuterium arc lamp), an Xe gas discharge lamp or an Hg vapor lamp. Alternatively, an F2 excimer laser (at a wavelength of 157 nm) may also be used.

The fluorination chamber may be sealed in a gas-tight manner. The conversion products of the active fluorination agent mean the fluorine species and the chemical compounds formed therefrom (for example HF). Stability should be understood for example in the sense that a passivating layer is formed on the inner side of the fluorination chamber. For example, there is to be no formation of volatile fluorine compounds that can be precipitated on the optical element treated in the fluorination chamber. The fluorination chamber, especially the inner side thereof, can for example be manufactured at least partly from a metallic material which should typically be free of Cr and Ti, in order to prevent corrosion. The fluorination chamber may have been manufactured from Monel steel for example.

Alternatively, the inner side of the fluorination chamber may have a fluorine-stable coating in order to prevent corrosion. Such a coating can be applied by a galvanic process. Suitable materials are Ni, NiP, Pt or Ru/Rh mixtures for example.

The supply unit can be designed to introduce the active fluorination agent, diluted in the inert gas, into the fluorination chamber. Furthermore, the supply unit may comprise a suitable metering valve, for example a mass flow controller, in order to set the partial pressure of the active fluorination agent in the fluorination chamber to a desired value.

The device can moreover comprise a fluorine gas sensor and/or a dedicated sensor for the active fluorination agent. The device may further comprise a closed-loop controller for controlling the partial pressure of the active fluorination agent, control optionally being brought about via the measured values from the fluorine gas sensor and/or dedicated sensor for the active fluorination agent.

Hence, the partial pressure of the active fluorination agent may firstly be set indirectly by setting the flow or else be actively controlled by way of a sensor and a closed-loop controller.

The device may comprise one or more further fluorine-resistant sensors for determining the O₂ and/or H₂O partial pressure in the aftertreatment chamber.

The device may optionally comprise a second UV/VUV radiation source that emits UV/VUV radiation in a second spectral range for the purpose of mobilizing atoms at the surface and/or in the volume of the oxide layer and/or of the newly formed fluoride or oxyfluoride layer, as described above in the context of the method. In an alternative to that, the device may also comprise only one UV/VUV radiation source that emits UV/VUV radiation in the first and second spectral ranges.

In order to anneal at least one crystal defect of the fluoride or oxyfluoride layer, the UV/VUV radiation source and/or the second UV/VUV radiation source may further optionally emit in a spectral range that at least partly overlaps with the absorption range of the at least one crystal defect. In an alternative to that, the device may also comprise one or more further radiation sources that serve to anneal the at least one crystal defect of the fluoride layer and emit further electromagnetic radiation in a spectral range that at least partly overlaps with the absorption range of the at least one crystal defect. Thus, at least one radiation source may be suitable for bleaching crystal defects that arise in the fluoride or oxyfluoride layer during the conversion. The spectral ranges can be adaptable to the absorption range or the absorption ranges of the crystal defects. For example, the further radiation source or further radiation sources may be one or more tunable radiation sources (for example based on a broadband primary light source with a downstream wavelength selection). In an alternative to that or in addition, a dedicated radiation source may also be used for the oxide to be converted or for each of the oxides to be converted.

Further features and aspects of the disclosure are evident from the following description of exemplary embodiments of the disclosure, with reference to the figures of the drawing, which show details relevant to the disclosure, and from the claims. The individual features can be implemented individually in their own right or collectively in any combination in a variant of the disclosure.

### BRIEF DESCRIPTION OF THE DRAWINGS

Exemplary embodiments are shown in the schematic drawing and are explained in the description which follows.

FIG. 1 shows a schematic illustration of three snapshots of a method in which a dense oxide layer is deposited and converted into a fluoride or oxyfluoride layer by subsequent irradiation with VUV radiation in the presence of an active fluorination agent.

FIG. 2 shows a schematic illustration of the absorption and spectral ranges relevant to the irradiation of the oxide layer.

FIG. 3 shows a schematic illustration of a device for forming the fluoride or oxyfluoride layer by converting the oxide layer in the presence of the active fluorination agent.

FIGS. 4A and 4B show the formation enthalpies or the difference between the formation enthalpies of three selected oxides and fluorides.

FIGS. 5A and 5B show two examples of a procedure for producing an optical element for reflecting VUV radiation by the method presented in FIG. 1.

FIG. 6 shows a schematic illustration of an optical arrangement for the VUV wavelength range in the form of a VUV lithography apparatus.

FIG. 7 shows a schematic illustration of an optical arrangement for the VUV wavelength range in the form of a wafer inspection system.

### DETAILED DESCRIPTION

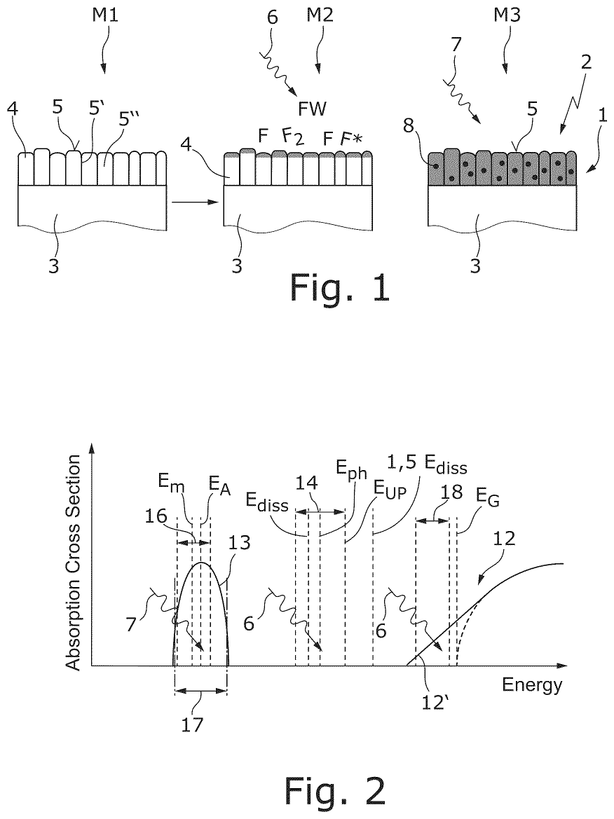

FIG. 1 shows a schematic illustration of the formation of a fluoride or oxyfluoride layer 1 of an optical element 2 for use in the VUV wavelength range. Three snapshots M1, M2, M3 of a substrate 3 of the optical element 2 are depicted during the formation of the fluoride or oxyfluoride layer 1.

The first snapshot M1 depicted to the left in FIG. 1 shows the substrate 3 following the deposition of a dense oxide layer 4, which consists of MgO in the example shown. The dense oxide layer 4 is deposited by a PVD deposition process known per se, for example by sputter deposition, for example magnetron sputtering, ion beam sputtering (IBS), ion beam-assisted sputtering (IBAS) or plasma ion-assisted deposition (PIAD). Deposition in a CVD deposition process, which may for example comprise an atomic layer deposition process (ALD) or a plasma-enhanced atomic layer deposition process (PEALD), is also possible.

The oxide layer 4 is deposited in a coating chamber that is not shown pictorially in FIG. 1. The substrate 3 with the deposited oxide layer 4 is taken from the coating chamber and transferred to a fluorination chamber (likewise not shown pictorially in FIG. 1), as indicated by an arrow in FIG. 1.

The second snapshot M2 depicted in the center of FIG. 1 shows the oxide layer 4, more precisely a surface 5 of the oxide layer 4 facing the surroundings, during the irradiation with UV/VUV radiation 6 in the presence of an active fluorination agent FW. As a consequence of the irradiation, the active fluorination agent FW dissociates and forms fluorine species F, F₂, F*. The fluorine species F, F₂, F* react with the oxide of the oxide layer 4 present at the surface 5 and convert the oxide into a fluoride (MgF₂ in the present case). By way of example, the active fluorination agent FW is NF₃, but it may also be a different substance that is able to provide the fluorine species F, F₂, F* by way of photodissociation, for example at least one substance from the group comprising: F₂, HF, XeF₂, CF₄ and SF₆.

The third snapshot M3 depicted to the right in FIG. 1 shows a fluoride layer 1, into which the oxide layer 4 was converted during the fluorination. The fluoride layer 1 is an (at least approximately) stoichiometric fluoride. The optical performance of the optical element 2 is improved significantly by the conversion of the dense oxide layer 4 into the fluoride layer 1. Unlike what was described above, an oxyfluoride layer, rather than the fluoride layer 1, may be formed during the conversion. This occurs when not all of the oxide in the oxide layer is converted into a fluoride. The degree of conversion of the oxide in the oxide layer 4 into a fluoride depends on various influencing factors, inter alia on the thickness of the oxide layer 4 and the duration of irradiation.

Furthermore, the fluoride layer 1 is irradiated by further electromagnetic radiation 7 during the aftertreatment in the example illustrated, but this is not mandatory. This serves the annealing of crystal defects 8 in the fluoride layer 1. In an alternative to that or in addition, the irradiation by the further electromagnetic radiation 7 may occur during the irradiation of the oxide layer 4, for the purpose of annealing crystal defects 8 in the already converted portion of the fluoride layer 1.

Moreover, the oxide layer 4 may additionally be heated during the irradiation, although this is not depicted in FIG. 1. However, heating is not a mandatory constituent of the method.

FIG. 2 illustrates the absorption and spectral ranges relevant to the irradiation of the oxide layer 4. Energy is plotted on the abscissa axis, and the absorption cross section is plotted on the ordinate axis. The dissociation energy E_{diss} of the active fluorination agent FW, the absorption cross section 12 of the fluoride or oxyfluoride layer 1 to be newly formed, including an Urbach tail 12′, and the absorption cross section 13 of a crystal defect 10 in the fluoride or oxyfluoride layer 1 are depicted schematically.

The UV/VUV radiation 6 used to irradiate the oxide layer 4 has a first spectral range 14 for the photodissociation of the active fluorination agent FW. By way of example, the first spectral range 14 comprises at least one wavelength whose energy Eₚₕ is at least equal to the dissociation energy E_{diss} of the active fluorination agent FW.

Further, the highest energy E_{UP} of the first spectral range 14 here is less than 50% greater than the dissociation energy E_{diss} of the active fluorination agent FW (i.e. less than 1.5×E_{diss}; cf. FIG. 2); this is exemplary and not mandatory. This suppresses potentially negative and/or competing effects. The highest energy E_{UP} of the first spectral range 14 may also be no more than the band gap energy EG of the oxide layer 4, such as no more than 75% of the band gap energy EG of the oxide layer 4.

Moreover, the fluoride or oxyfluoride layer 1 is irradiated with further electromagnetic radiation 7 by way of example, this serving the annealing of at least one crystal defect 10 in the fluoride or oxyfluoride layer 1. To this end, the further electromagnetic radiation 7 includes a spectral range 16 that overlaps with the absorption range 17 of the at least one crystal defect 10. In the illustrated example, the spectral range 16 of the further electromagnetic radiation 9 lies within the absorption range 17 of the crystal defect 8, which is an F center; however, this is not necessarily required. In an alternative to that, the UV/VUV radiation 6 may also include a corresponding spectral range.

In the illustrated example, the spectral range 16 of the further electromagnetic radiation 9 comprises the absorption energy E_{A} of the crystal defect 10 at which the absorption cross section is maximal. However, this is not necessarily the case. The absorption range 17 of the crystal defect 10 is defined by a drop to one hundredth of the maximum value of the absorption cross section (FWHM) at the absorption energy E_{A} of the crystal defect 10. Further, it is desirable if a mean energy Eₘ (arithmetic mean) of the spectral range 16 deviates from the absorption energy E_{A} of the crystal defect 10 by no more than 0.5 eV, for example by no more than 0.25 eV.

Moreover, the UV/VUV radiation 8 includes a second spectral range 18 for mobilizing atoms at the surface 5, at the grain boundaries 5′ and/or in the grain volume 5″ of the fluoride or oxyfluoride layer 1 to be newly formed, which correspond to the grain boundaries 5′ and the grain volume 5″ of the oxide layer 4. In the illustrated example, this second spectral range 18 lies in an energy range of between 75% and 100% of the band gap energy E_{G} of the fluoride or oxyfluoride layer 1. The second spectral range 18 may also lie between 80% and 95% of the band gap energy E_{G} of the fluoride or oxyfluoride layer 1.

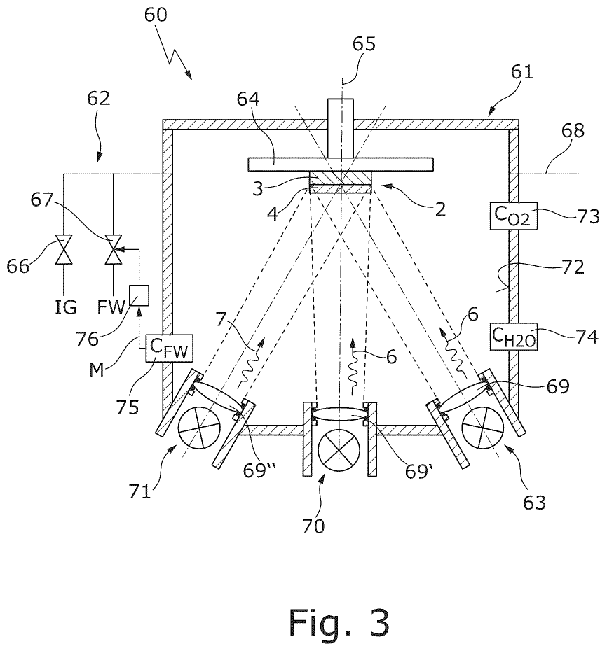

FIG. 3 shows a device 60 for forming the fluoride or oxyfluoride layer 1 of the optical element 2 from FIG. 1 by converting the oxide layer 4 into the fluoride or oxyfluoride layer 1. The device 60 comprises a fluorination chamber 61, supply unit 62 and a UV/VUV radiation source 63.

The optical element 2 that comprises the oxide layer 4, which is applied to a substrate 3 in exemplary fashion in this case, is attached to a substrate holder 64, which is rotatable about a rotation axis 65, within the fluorination chamber 61. However, deviating from the example illustrated here, the device 60 need not comprise a rotatable substrate holder 64.

The supply unit 62 serves to supply protective gas, which is in the form of inert gas IG, and the active fluorination agent FW into the fluorination chamber 61, the supply unit 62 comprising a first valve 66 for controlled supply of the inert gas IG and a second valve 67 for controlled supply of the active fluorination agent FW. The second valve 67 is a controllable metering valve. As a consequence, the oxide layer 4 may be irradiated in the presence of the active fluorination agent FW in a protective gas atmosphere within the fluorination chamber 61. The device 60 moreover comprises a gas outlet 68 for letting out the inert gas IR and reaction products formed during the fluorination. In the example illustrated, the inert gas IR is argon, but it is also possible to use other inert gases IR, for example other light noble gases such as helium or neon. Mixtures of noble gases, for example of the noble gases mentioned, can also be used as inert gas IR.

The UV/VUV radiation source 63 serves to irradiate the oxide layer 4 with UV/VUV radiation 6 in the presence of the active fluorination agent FW in the fluorination chamber 61. By way of example, in the illustrated example, the UV/VUV radiation 6 enters the fluorination chamber 61 through an MgF₂ window 69. The VUV radiation source 63 serves to generate UV/VUV radiation 6 in the above-described first spectral range 14.

Moreover, by way of example, the device 60 in this case comprises—although this is not mandatory—a second UV/VUV radiation source 70 for irradiating the oxide layer 4 with UV/VUV radiation 7 in the above-described second spectral range 18 for mobilizing atoms at the surface 5, at the grain boundaries 5′ and/or in the grain volume 5″ of the oxide layer 4. In the illustrated example, the UV/VUV radiation 7 from the second UV/VUV radiation source 70 enters the fluorination chamber 61 through an MgF₂ window 69′. The device 60 also comprises a further radiation source 71 for irradiating the fluoride or oxyfluoride layer 1, formed during the conversion, with further electromagnetic radiation 7 in the spectral range 17, described above in the context of FIG. 2, for annealing at least one crystal defect 10 in the fluoride or oxyfluoride layer 1. The further electromagnetic radiation 7 from the further radiation source 71 enters the fluorination chamber 61 through a further MgF₂ window 69″.

In place of at least one of the MgF₂ windows 69, 69′, 69″, it is possible in principle to also use windows made of other materials, for example from CaF₂, SrF₂ and/or BaF₂, with sufficient transparency at the utilized wavelengths being decisive in this respect.

The fluorination chamber 61 may be sealed in a gas-tight manner. Furthermore, the inner side 72 of the fluorination chamber 61 is resistant to the active fluorination agent FW and its conversion products. For this purpose, in the example illustrated, the fluorination chamber 61, at least on its inner side 72, is formed from a metal in the form of Monel steel, which forms a passivating layer in order to prevent corrosion. In principle, the fluorination chamber 61 can also be formed from other corrosion-resistant metals if the latter are free of Cr and Ti.

Alternatively, a corrosion-resistant coating, e.g. composed of NiP, Pt or Ru/Rh mixtures, can be applied to the inner side 72 of the fluorination chamber 61. The corrosion-resistant coating can be applied to the inner side 72 of the fluorination chamber 61 via a galvanic process, for example. The components which are arranged in the fluorination chamber 61 and which come into contact with the active fluorination agent FW are likewise resistant to the active fluorination agent FW and the conversion products thereof.

Further the device 60 depicted here comprises, by way of example but not necessarily, a sensor 73 for measuring the oxygen concentration c_{O2} in the fluorination chamber 61 and a further sensor 74 for measuring the H₂O concentration c_{H2O} in the fluorination chamber 61.

By way of example, the oxygen concentration c_{O2} in the fluorination chamber 61 is less than 50 ppbV during the irradiation of the oxide layer 4 or the conversion. The oxygen concentration c_{O2} should be as low as possible, although it may also be greater than 50 ppbV. However, it is desirable for the oxygen concentration c_{O2} to be less than 10 ppmV, such as less than 1 ppmV, for example less than 100 ppbV.

Further, in the illustrated example, the H₂O concentration c_{H2O} in the fluorination chamber 61 is less than 100 ppbV during the irradiation of the oxide layer 4. In principle, the H₂O concentration c_{H2O} in the fluorination chamber 61 during the irradiation of the oxide layer 4 should be as low as possible, although the H₂O concentration c_{H2O} may also be greater than 100 ppbV. However, it is desirable for the H₂O concentration c_{H2O} to be less than 10 ppmV, such as less than 1 ppmV, for example less than 500 ppbV.

Although this is not mandatory, the device 60 of the illustrated example moreover comprises a sensor 75 for measuring the partial pressure c_{FW} of the active fluorination agent FW in the fluorination chamber 61 and a closed-loop controller 76 for adjusting the partial pressure c_{FW} of the active fluorination agent FW in the fluorination chamber 61 to a target value, the control being implemented via the actual measured value M from the sensor 75 for measuring the partial pressure crw of the active fluorination agent FW in the fluorination chamber 61 and via the control of the second valve 67. The sensor 75 may be designed to measure only the partial pressure cow of the active fluorination agent FW; however, it may also be a residual gas analyzer that is able to also determine the partial pressures of other gases contained in the fluorination chamber 21. It is possible that such a residual gas analyzer assumes the function of the three sensors 73, 74, 75 depicted in FIG. 3. If the second valve 67 is a metering valve, for example a mass flow regulator, then it is possible to dispense with the use of the sensor 75 for measuring the partial pressure c_{FW} of the active fluorination agent FW in the fluorination chamber 61.

The active fluorination agent FW is added to the inert gas IR in the supply unit 62. The partial pressure c_{FW} of the active fluorination agent FW in the aftertreatment chamber 61 lies typically between 0.05 and 10⁶ ppmV, such as between 0.075 ppmV and 50 ppmV, for example between 0.1 ppmV and 10 ppmV, during the irradiation of the oxide layer 4.

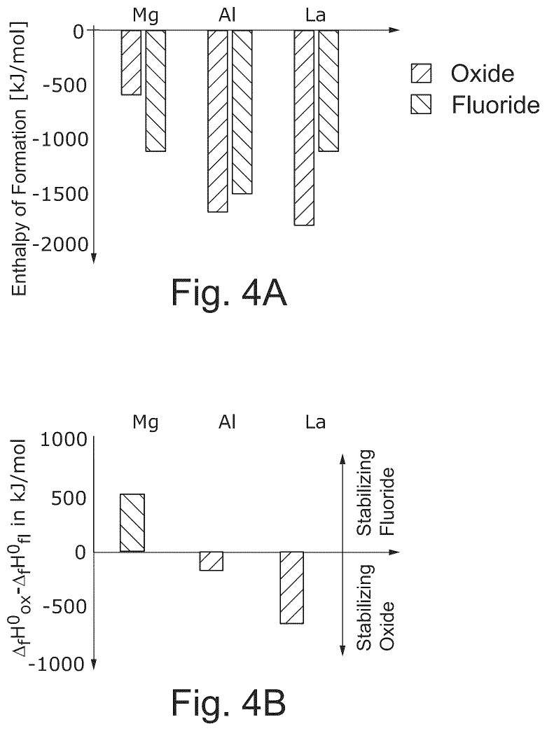

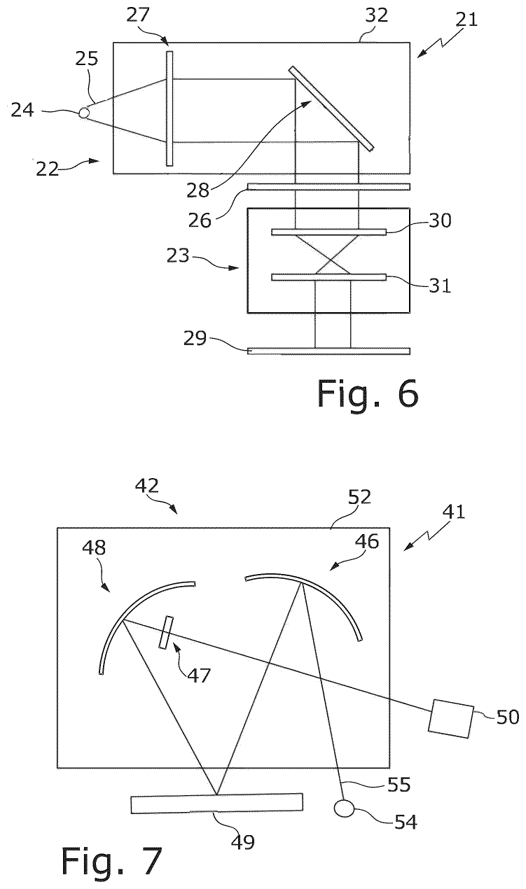

In principle, the chemically and energetically driven conversion of an oxide into a fluoride works particularly well whenever the fluoride MₓF_{y}(M=metal, F=fluorine) is more stable than the oxide MₐO_{b}. FIG. 4A shows, by way of example, the formation enthalpy (in kJ/mol) for the three substance pairs MgO/MgF₂, Al₂O₃/AlF₃ and La₂O₃/LaF₃. FIG. 4B shows the difference between the formation enthalpy Δ_{f}H⁰ₒₓ of the oxide and the formation enthalpy Δ_{f}H⁰_{fl} of the corresponding fluoride for the three chemical elements Mg, Al and La. For a positive value of the difference Δ_{f}H⁰ₒₓ−Δ_{f}H⁰_{fl}, the fluoride of the respective substance pair is more stable than the oxide. As evident from FIG. 6b, this is only the case for Mg from among the three elements shown, i.e. for Mg there is a pronounced driving force to convert the oxide into the corresponding fluoride. Experiments have demonstrated a significant reduction in extinction for Al₂O₃, too, following the above-described fluorination step. Evaluation of the experiments suggests that the conversion of Al₂O₃ to AlF₃ works slightly less well—in agreement with the prediction from the formation enthalpies—than the conversion of MgO to MgF₂. The conversion of other oxides to fluorides or oxyfluorides is also possible, for example the conversion of Gd₂O₃ to GdF₃, of CaO to CaF₂, of SrO to SrF₂ or of BaO to BaF₂.

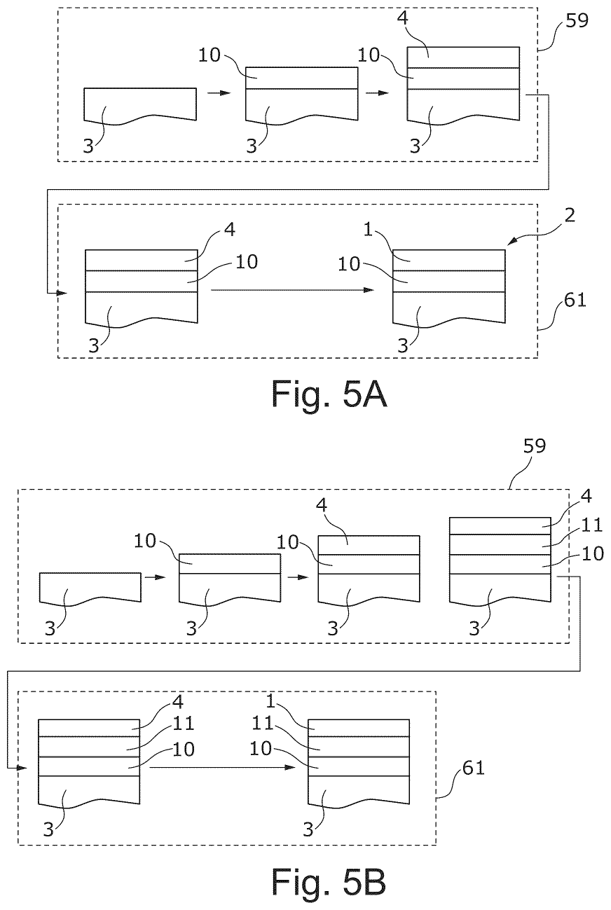

The method described above in the context of FIG. 1 may find use for the production of different optical elements. Two examples for the production of an optical element 2 in the form of a mirror that reflects radiation in the VUV wavelength range in broadband fashion are described below on the basis of FIG. 5A and FIG. 5B.

In the example shown in FIG. 5A, the substrate 3 is introduced into a coating chamber 59 in order to perform a coating process, in which, in a first step, a metallic reflection layer in the form of an aluminum layer 10 is deposited on the substrate 3 by a conventional deposition method. In a subsequent step on the aluminum layer 10, the dense oxide layer 4 described in the context of FIG. 1 is deposited on the aluminum layer 10 via a plasma-assisted coating method (see above).

Since the aluminum layer 10 is protected from environmental influences by the oxide layer 4, the substrate 3 with the deposited aluminum layer 10 and the oxide layer 4 may be taken from the coating chamber 59 and introduced into the fluorination chamber 61, which is part of the device 60 shown in FIG. 3. The fluorination process which is described in the context of FIG. 3, which follows the coating process and in which the oxide layer 4, e.g. in the form of an MgO layer, is converted into the fluoride or oxyfluoride layer 1 takes place in the fluorination chamber 61.

In the example shown in FIG. 5B, the deposition of the dense oxide layer 4 is preceded by the deposition of a (further) fluoride layer 11, possibly made e.g. of MgF₂, on the aluminum layer 10. A comparatively thin, dense oxide layer 4 is deposited on the fluoride layer 11, as described in the context of FIG. 1. In a manner analogous to the example described in FIG. 5A, the substrate 3 is taken from the coating chamber 59 and transferred into the fluorination chamber 61, in which the fluorination process for converting the oxide layer 4 into a fluoride layer 1 takes place. In the example described in FIG. 5B, the oxide layer 4, which is deposited on the further fluoride layer 11, is comparatively thin, typically 5-10 nm, and is therefore, unlike the example described in FIG. 5A, converted not into an oxyfluoride layer but into a fluoride layer 1. However, the oxide layer 4 may also have a thicker embodiment.

The above-described optical element 2, which comprises the fluoride or oxyfluoride layer 1, may be used in different optical arrangements for the VUV wavelength range.

FIG. 6 shows an optical arrangement for the VUV wavelength range in the form of a VUV lithography apparatus 21. The VUV lithography apparatus 21 comprises two optical systems, namely an illumination system 22 and a projection system 23. The VUV lithography apparatus 21 additionally comprises a radiation source 24, which may be an excimer laser, for example.

The radiation 25 emitted by the radiation source 24 is conditioned with the aid of the illumination system 22 such that a mask 26, also called a reticle, is illuminated thereby. In the example shown, the illumination system 22 comprises a housing 32, in which both transmissive and reflective optical elements are arranged. In a representative manner, the illustration shows a transmissive optical element 27, which focuses the radiation 25, and a reflective optical element 28, which deflects the radiation.

The mask 26 comprises, on its surface, a structure which is transferred to an optical element 29 to be exposed, for example a wafer, with the aid of the projection system 23 for the purpose of producing semiconductor components. In the example shown, the mask 26 is designed as transmissive optical element. In alternative embodiments, the mask 26 may also be designed as reflective optical element.

The projection system 22 comprises at least one transmissive optical element in the example illustrated. The example shown illustrates, in a representative manner, two transmitting optical elements 30, 31, which serve, for example, to reduce the structures on the mask 26 to the size desired for the exposure of the wafer 29.

Both in the illumination system 22 and in the projection system 23, a wide variety of transmissive, reflective or other optical elements can be combined with one another as desired, including in a more complex manner. Optical arrangements without transmissive optical elements can also be used for VUV lithography.

FIG. 7 shows an optical arrangement for the VUV wavelength range in the form of a wafer inspection system 41, but this may also be a mask inspection system. The wafer inspection system 41 comprises an optical system 42 with a radiation source 54, from which the radiation 55 is directed onto a wafer 49 via the optical system 42. For this purpose, the radiation 55 is reflected off a concave mirror 46 to the wafer 49. In the case of a mask inspection system, it would be possible to replace the wafer 49 with a mask to be examined. The radiation reflected, diffracted and/or refracted by the wafer 49 is directed onto a detector 50 for further evaluation by a further concave mirror 48, which is likewise associated with the optical system 42, via a transmissive optical element 47. The wafer inspection system 41 additionally comprises a housing 52, in which the two mirrors 46, 48 and the transmissive optical element 47 are arranged. The radiation source 54 may, for example, be exactly one radiation source or a combination of a plurality of individual radiation sources in order to provide a substantially continuous radiation spectrum. In modifications, it is also possible to use one or more narrowband radiation sources 54.

At least one of the optical elements 27, 28, 30, 31 of the VUV lithography apparatus 21 shown in FIG. 6 and at least one of the optical elements 46, 47, 48 of the wafer inspection system 41 shown in FIG. 7 are designed here as described above. The at least one of the optical elements 27, 28, 30, 31, 46, 47, 48 thus comprises (at least) one fluoride or oxyfluoride layer that was formed or produced by the above-described method.

What is claimed is:

1. A method, comprising:
depositing an oxide layer on an optical element; and
converting the oxide layer into a fluoride or oxyfluoride layer by irradiating the oxide layer with UV/VUV radiation in the presence of an active fluorination agent.

2. The method of claim 1, comprising using physical vapor deposition to deposit the oxide layer on the optical element.

3. The method of claim 1, comprising using chemical vapor deposition to deposit the oxide layer on the optical element.

4. The method of claim 1, wherein the oxide layer is deposited in a coating chamber, and the oxide layer is converted into the fluoride or oxyfluoride layer in a fluorination chamber that is spatially separate from the coating chamber.

5. The method of claim 1, wherein the UV/VUV radiation comprises a first spectral range comprising a wavelength whose energy is at least equal to a dissociation energy of the active fluorination agent.

6. The method of claim 5, wherein a highest energy of the first spectral range is at most 100% greater than the dissociation energy of the active fluorination agent.

7. The method of claim 5, wherein a highest energy of the first spectral range is at most a band gap energy of the fluoride or oxyfluoride layer.

8. The method of claim 5, wherein the UV/VUV radiation comprises a second spectral range in a range of between 75% and 100% of a band gap energy of the fluoride or oxyfluoride layer.

9. The method of claim 1, wherein the UV/VUV radiation comprises a second spectral range in a range of between 75% and 100% of a band gap energy of the fluoride or oxyfluoride layer.

10. The method of claim 1, wherein the UV/VUV radiation or further electromagnetic radiation additionally used to irradiate the fluoride or oxyfluoride layer formed during the conversion comprises a spectral range that at least partly overlaps with an absorption range of at least one crystal defect.

11. The method of claim 1, wherein the oxide layer is irradiated in a protective gas atmosphere.

12. The method of claim 1, wherein the active fluorination agent comprises at least one member selected from the group consisting of F₂, HF, XeF₂, NF₃, CF₄, and SF₆.

13. The method of claim 12, further comprising, before depositing the oxide layer, depositing a further fluoride layer on the substrate of the optical element.

14. The method of claim 1, wherein, when irradiating the oxide layer, a partial pressure of the active fluorination agent lies between 0.05 and 10⁶ parts per million by volume.

15. The method of claim 1, wherein the oxide layer comprises a member selected from the group consisting of an MgO layer, an Al₂O₃ layer, an La₂O₃ layer, a Gd₂O₃ layer, a CaO layer, an SrO layer, and a BaO layer.

16. The method of claim 1, wherein the fluoride or oxyfluoride layer comprises a member selected from the group consisting of an MgF₂ layer, an MgₓO_{y}F_{z} layer, an AlF₃ layer, an AlₓO_{y}F_{z} layer, an LaF₃ layer, an LaₓO_{y}F_{z} layer, a GdF₃ layer, a GdₓO_{y}F_{z} layer, a CaF₂ layer, a CaxOvF_{z} layer, an SrF₂ layer, an SrₓO_{y}F_{z} layer, a BaF₂ layer, and a BaₓO_{y}F_{z} layer.

17. The method of claim 1, further comprising, before depositing the oxide layer, depositing a metallic reflection layer on a substrate of the optical element.

18. An optical element, comprising:
a substrate; and
a fluoride or oxyfluoride layer prepared according to the method of claim 1,
wherein the substrate supports the fluoride or oxyfluoride layer.

19. An optical arrangement, comprising:
an optical element, comprising:
a substrate; and
a fluoride or oxyfluoride layer prepared according to the method of claim 1, wherein the substrate supports the fluoride or oxyfluoride layer.

20. A device, comprising:
a fluorination chamber;
a supply unit configured to supply inert gas and an active fluorination agent into the fluorination chamber, an inner side of the fluorination chamber being resistant to the active fluorination agent and its conversion products; and
a UV/VUV radiation source configured to irradiate an oxide layer of an optical element in the fluorination chamber with UV/VUV radiation in the presence of an active fluorination agent in the fluorination chamber to convert the oxide layer into the fluoride or oxyfluoride layer.
